(19) United States
(12) Patent Application Publication
(10) Pub. No.: US 2026/0121004 A1
(43) Pub. Date: Apr. 30, 2026

(54) SEMICONDUCTOR PROCESSING EQUIPMENT

(71) Applicant: SAMSUNG ELECTRONICS CO., LTD., Suwon-si (KR)

(72) Inventors: MINNHOO CHOI, Suwon-si (KR); HAEWOOK PARK, Suwon-si (KR); SANGHOON JUNG, Suwon-si (KR); JUNHO IM, Suwon-si (KR)

(73) Assignee: SAMSUNG ELECTRONICS CO., LTD., Suwon-si (KR)

(21) Appl. No.: 19/207,982

(22) Filed: May 14, 2025

(30) Foreign Application Priority Data
Oct. 31, 2024 (KR) 10-2024-0152170

(51) Int. Cl. H01J 37/32; H01L 21/683

(52) U.S. Cl. CPC H01J 37/3299; H01J 37/32174; H01J 37/32715; H10P 72/72; H01J 2237/334

(57) ABSTRACT

A semiconductor processing equipment includes a chamber housing, an electrostatic chuck in the chamber housing, a lower electrode below the electrostatic chuck in the chamber housing, an upper electrode above the electrostatic chuck in the chamber housing, a first power supply that supplies first radio frequency (RF) power to the lower electrode, a second power supply that supplies second RF power to the upper electrode, a first voltage and current (VI) sensor between the lower electrode and an inner wall of the chamber housing, a second VI sensor between the upper electrode and the inner wall of the chamber housing, and a controller that determines a phase of the first and second RF powers using the first and second VI sensors, controls the first and second power supplies, based on the determined phases.

### CROSS-REFERENCE TO RELATED APPLICATION

This application is based on and claims priority to Korean Patent Application No. 10-2024-0152170 filed on Oct. 31, 2024 in the Korean Intellectual Property Office, the disclosure of which being incorporated by reference herein in its entirety.

### BACKGROUND

The present disclosure relates to semiconductor processing equipment.

Semiconductor processing equipment may be equipment for performing various semiconductor processes on a substrate such as a wafer or the like, based on plasma formed in the semiconductor processing equipment. Radicals, ions, or the like may form the plasma by radio frequency (RF) power supplied to the semiconductor processing equipment, and semiconductor processes such as deposition, etching, cleaning, or the like may be performed. In order to perform the semiconductor process uniformly, regardless of a position of the substrate, it is necessary to accurately detect the RF power supplied to the semiconductor processing equipment.

### SUMMARY

It is an aspect to provide semiconductor processing equipment capable of improving uniformity of a semiconductor process by installing a sensor detecting a voltage and/or a current inside a chamber housing to precisely control RF power respectively supplied to a lower electrode and an upper electrode, in order to monitor the RF power respectively supplied to the lower electrode and the upper electrode.

According to an aspect of one or more embodiments, there is provided a semiconductor processing equipment comprising a chamber housing; an electrostatic chuck in the chamber housing; a lower electrode below the electrostatic chuck in the chamber housing; an upper electrode above the electrostatic chuck in the chamber housing; a first power supply configured to supply first radio frequency (RF) power to the lower electrode; a second power supply configured to supply second RF power to the upper electrode; a first voltage and current (VI) sensor between the lower electrode and an inner wall of the chamber housing; a second VI sensor between the upper electrode and the inner wall of the chamber housing; and a controller configured to determine a phase of the first RF power using a sensing signal of the first VI sensor, determine a phase of the second RF power using a sensing signal of the second VI sensor, and control the first power supply and the second power supply, based on the phase of the first RF power and the phase of the second RF power.

According to another aspect of one or more embodiments, there is provided a semiconductor processing equipment comprising a chamber housing; an electrostatic chuck in the chamber housing; a lower electrode below the electrostatic chuck in a first direction that is perpendicular to an upper surface of the electrostatic chuck, and connected to a lower rod providing a first transmission path of the first RF power; an upper electrode above the electrostatic chuck in the first direction and connected to an upper rod providing a second transmission path of the second RF power; a first voltage and current (VI) sensor coupled to the lower rod in the chamber housing; and a second VI sensor coupled to the upper rod in the chamber housing.

According to yet another aspect of one or more embodiments, there is provided a semiconductor processing equipment comprising a chamber housing; an electrostatic chuck in the chamber housing; a lower electrode below the electrostatic chuck and receiving first RF power; an upper electrode above the electrostatic chuck and receiving second RF power that is generated independently of the first RF power; a first VI sensor in the chamber housing closer to the lower electrode than to the upper electrode; a second VI sensor in the chamber housing closer to the upper electrode than to the lower electrode; and a controller configured to detect a first harmonic component included in the first RF power from the first voltage and current (VI) sensor, detect a second harmonic component included in the second RF power from the second VI sensor, and control a phase of at least one of the first RF power or the second RF power with reference to the first harmonic component and the second harmonic component.

### BRIEF DESCRIPTION OF DRAWINGS

The above and other aspects will be more clearly understood from the following detailed description, taken in conjunction with the accompanying drawings, in which:

FIG. 1 is a view schematically illustrating a system including semiconductor processing equipment according to an embodiment;

FIG. 2 is a view schematically illustrating semiconductor processing equipment according to an embodiment;

FIG. 3 is a view illustrating uniformity of a semiconductor process performed in semiconductor processing equipment according to an embodiment;

FIGS. 4 and 5 are views schematically illustrating semiconductor processing equipment according to an embodiment;

FIGS. 6A and 6B are views schematically illustrating a voltage and current (VI) sensor included in semiconductor processing equipment according to an embodiment;

FIG. 7 is a view schematically illustrating a voltage and current (VI) sensor included in semiconductor processing equipment according to an embodiment;

FIGS. 8 and 9 are views illustrating an operation of a voltage and current (VI) sensor included in semiconductor processing equipment according to an embodiment;

FIGS. 10 and 11 are views illustrating an operation of semiconductor processing equipment according to an embodiment; and

FIGS. 12 and 13 are flowcharts illustrating an operation of semiconductor processing equipment according to an embodiment.

### DETAILED DESCRIPTION

Semiconductor processing equipment may be equipment having a chamber shape and performing various semiconductor processes on a substrate such as a wafer or the like, and plasma may be formed in the chamber while a semiconductor process is being performed. Radicals, ions, or the like may form plasma by radio frequency (RF) power supplied to the semiconductor processing equipment, and semiconductor processes such as deposition, etching, cleaning, or the like may be performed. The semiconductor processing equipment may include a lower electrode and an upper electrode, receiving RF power, and uniformity of the semiconductor process performed on a substrate such as a wafer or the like may be changed depending on the RF power applied to each of the lower electrode and the upper electrode. Therefore, as discussed above, in order to perform the semiconductor process uniformly, regardless of a position of the substrate, it is advantageous to accurately detect the RF power supplied to each of the lower electrode and the upper electrode.

A semiconductor processing equipment according to various embodiments may improve uniformity of a semiconductor process by installing a sensor detecting a voltage and/or a current inside a chamber housing to precisely control RF power respectively supplied to a lower electrode and an upper electrode, in order to monitor the RF power respectively supplied to the lower electrode and the upper electrode.

Hereinafter, various embodiments will be described with reference to the attached drawings. As used in this specification, a phrase using the form “at least one of A or B” includes within its scope “only A”, “only B”, and “A and B”, and a phrase using the form “at least one of A, B, or C” includes within its scope “only A”, “only B”, “only C”, “A and B”, “A and C”, “B and C” and “A, B, and C.”

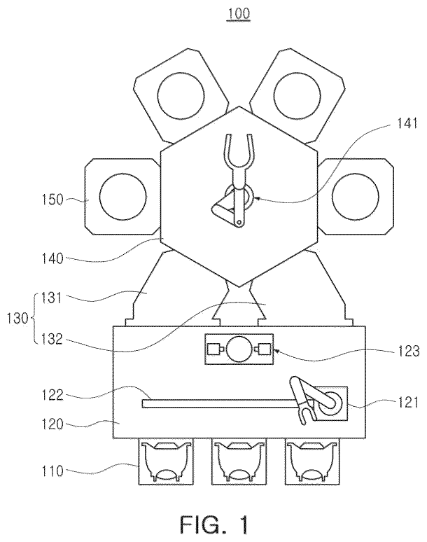

FIG. 1 is a view schematically illustrating a system including semiconductor processing equipment according to an embodiment.

Referring to FIG. 1, processing equipment 100 according to an embodiment may include a wafer transfer device 120, a load-lock chamber 130, a transfer chamber 140, a plurality of pieces of semiconductor processing equipment 150, and the like. For example, the wafer transfer device 120 may receive a wafer through a container such as a FOUP 110 or the like in a production line on which the processing equipment 100 is disposed. The wafer transfer device 120 may transfer the wafer received through the FOUP 110 to the load-lock chamber 130, or may receive a wafer on which a semiconductor process is completed in the semiconductor processing equipment 150 from the load-lock chamber 130 and store the same in the FOUP 110.

The wafer transfer device 120 may include a wafer transfer robot 121 having an arm capable of holding a wafer, a rail 122 moving the wafer transfer robot 121, an aligner 123 aligning the wafer, and the like. In an operation of transferring the wafer from the FOUP 110 to the load-lock chamber 130, the wafer transfer robot 121 may take out the wafer stored in the FOUP 110 and dispose the same on the aligner 123. The aligner 123 may rotate the wafer to align the wafer in a direction. The direction may be predetermined. When alignment of the wafer is completed in the aligner 123, the wafer transfer robot 121 may take the wafer out of the aligner 123, and may move the same to the load-lock chamber 130.

The load-lock chamber 130 may be connected to the wafer transfer device 120, and may include a loading chamber 131 in which wafers to be brought into the semiconductor processing equipment 150 for semiconductor process progress temporarily stay, an unloading chamber 132 in which wafers to be taken out from the semiconductor processing equipment 150 after the process is completed temporarily stay, and the like. When the wafer aligned in the aligner 123 is brought into the loading chamber 131, an inside of the loading chamber 131 may be depressurized to prevent external contaminants from entering.

The load-lock chamber 130 may be connected to the transfer chamber 140, and the plurality of pieces of semiconductor processing equipment 150 may be disposed around the transfer chamber 140. A wafer transfer robot 141 may be disposed in the transfer chamber 140 to transfer wafers between the load-lock chamber 130 and the plurality of pieces of semiconductor processing equipment 150. The wafer transfer robot 121 of the wafer transfer device 120 may be referred to as a first wafer transfer robot, and the wafer transfer robot 141 of the transfer chamber 140 may be referred to as a second wafer transfer robot.

Each of the plurality of pieces of semiconductor processing equipment 150 may perform a semiconductor process on the wafer. For example, the semiconductor process performed by the plurality of pieces of semiconductor processing equipment 150 may include a deposition process, an etching process, an exposure process, an annealing process, a polishing process, an ion implantation process, or the like.

To perform at least a portion of the semiconductor processes mentioned above, at least one of the plurality of pieces of semiconductor processing equipment 150 may include a lower electrode and an upper electrode that may be supplied with RF power to form plasma. The plasma may be formed on a substrate such as a display substrate, a wafer, or a mask, which may be a target of the semiconductor process, and progress of the semiconductor process may be changed depending on a position of the substrate by RF power applied to each of the lower electrode and the upper electrode.

For example, when a phase of first RF power applied to the lower electrode and a phase of second RF power applied to the upper electrode are not appropriately matched, a progress deviation of the semiconductor process according to the position of the substrate may increase, and uniformity of the semiconductor process may deteriorate. In an embodiment, when the semiconductor process is an etching process, the semiconductor process may progress faster in a region near a center of the substrate because the phases of the first RF power and the second RF power may not be appropriately matched.

To reduce the progress deviation of the semiconductor process according to the position of the substrate and improve the uniformity of the semiconductor process, it is advantageous to accurately detect each of the first RF power and the second RF power. For example, a first voltage and current (VI) sensor detecting the first RF power and a second VI sensor detecting the second RF power may be included in the semiconductor processing equipment 150. In an embodiment, the first VI sensor and the second VI sensor may be installed in a space in the chamber housing of the semiconductor processing equipment 150. Therefore, the first VI sensor may be installed as close as possible to the lower electrode, and the second VI sensor may also be installed as close as possible to the upper electrode, and the first RF power and the second RF power may be accurately detected.

In an embodiment, the first VI sensor may be coupled to a first rod that may be connected to the lower electrode and provides a transmission path for the first RF power, and the second VI sensor may be coupled to a second rod that may be connected to the upper electrode and provides a transmission path for the second RF power. By installing the first VI sensor and the second VI sensor such that a gap between the first VI sensor and the lower electrode may be equal to or similar to a gap between the second VI sensor and the upper electrode, asymmetry of the first VI sensor and the second VI sensor may be reduced and the first RF power and the second RF power may be accurately detected.

For example, a controller of the semiconductor processing equipment 150 may detect the first voltage and the first current from the first RF power using the first VI sensor, and may detect a second voltage and a second current from the second RF power using the second VI sensor. The controller may determine the phase of the first RF power using the first voltage and the first current, and may determine the phase of the second RF power using the second voltage and the second current. The controller may improve the uniformity of the semiconductor process by adjusting at least one of the first RF power supplied to the lower electrode or the second RF power supplied to the upper electrode with reference to the phase of the first RF power and the phase of the second RF power.

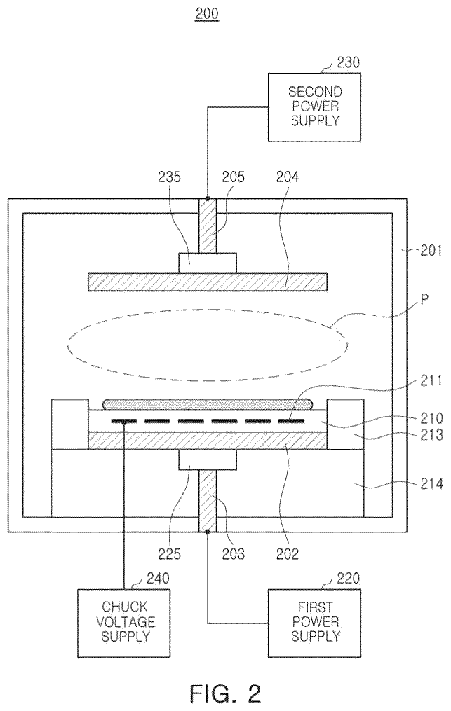

FIG. 2 is a view schematically illustrating semiconductor processing equipment according to an embodiment.

Referring to FIG. 2, semiconductor processing equipment 200 according to an embodiment may include a chamber housing 201, a lower electrode 202, an upper electrode 204, an electrostatic chuck 210, a first power supply 220, a second power supply 230, a first voltage and current (VI) sensor 225, a second VI sensor 235, and the like. The lower electrode 202, the upper electrode 204, the electrostatic chuck 210, the first power supply 220, the second power supply 230, the first VI sensor 225, the second VI sensor 235, or the like may be installed in a space in the chamber housing 201. In an embodiment, the chamber housing 201 may be formed of metal such as aluminum or the like, and may be electrically grounded.

The electrostatic chuck 210 may be disposed on the lower electrode 202, and a substrate such as a wafer W or the like, may be received on the electrostatic chuck 210. A chuck electrode 211 may be disposed in the electrostatic chuck 210, and the chuck electrode 211 may receive a bias voltage from a chuck voltage supply 240. The bias voltage may be predetermined. A Coulomb force may be generated by the bias voltage supplied to the chuck electrode 211 by the chuck voltage supply 240, and the wafer W may be fixed on the electrostatic chuck 210 by this Coulomb force. Depending on an embodiment, the bias voltage may be a voltage of several hundred to several thousand volts.

The electrostatic chuck 210 may include a plurality of protrusions directly contacting the wafer W. When the wafer W is disposed, a space may be formed between the plurality of protrusions, and the space between the plurality of protrusions may be filled with helium gas or the like to cool the wafer W.

The lower electrode 202 may be disposed below the electrostatic chuck 210. The lower electrode 202 may be physically connected to a lower rod 203, and the first power supply 220 may transmit first RF power to the lower electrode 202 through a power transmission path in the lower rod 203. The first power supply 220 may include an RF power source and a matching circuit, and in an embodiment, may supply first RF power of 60 MHz, 2 MHz, 400 kHz, or the like to the lower electrode 202.

A support member 214 may be installed below the lower electrode 202, and for example, the support member 214 may include a conductive material. At least one of the lower electrode 202 or the electrostatic chuck 210 may include a cooling means and/or a heating means capable of controlling a temperature of the wafer W. An insulator 213 may be disposed around the lower electrode 202 and the electrostatic chuck 210. In an embodiment, the insulator 213 may have a ring shape.

The upper electrode 204 may be an electrode forming a pair with the lower electrode 202, and each of the lower electrode 202 and the upper electrode 204 may be a plate-shaped electrode. The upper electrode 204 may be coupled to an upper rod 205 including a transmission path of second RF power output by the second power supply 230. For example, the transmission path of the second RF power may be implemented in the upper rod 205. In an embodiment, the second RF power supplied to the upper electrode 204 by the second power supply 230 may be the same as or different from the first RF power supplied to the lower electrode 202 by the first power supply 220. For example, the second power supply 230 may include an RF power source, a matching circuit, or the like, and may supply the second RF power having a frequency of 60 MHz to the upper electrode 204.

When the first RF power is applied to the lower electrode 202 and the second RF power is applied to the upper electrode 204, plasma P including ions, radicals, electrons, or the like of reaction gas injected into the chamber housing 201 may be formed in a space above the wafer W. According to an embodiment, the semiconductor processing equipment 200 may include an ion blocker disposed between the upper electrode 204 and the electrostatic chuck 210 and having a plurality of through-holes, and the plasma P may also be formed in a space between the upper electrode 204 and the ion blocker. When the semiconductor processing equipment 200 is etching equipment, the ions, the radicals, the electrons, or the like included in the plasma P may be accelerated to the wafer W by the first RF power and the second RF power, and the ions, the radicals, the electrons, or the like may collide with the wafer W to perform an etching process.

The wafer W may be divided by a scribing line or the like, and may include a plurality of semiconductor dies disposed in different locations, and to increase yield of the wafer W, it is advantageous to uniformly perform a semiconductor process on the plurality of semiconductor dies. For example, deviation of the semiconductor process according to a location of the wafer W may be reduced by controlling the first RF power and the second RF power, respectively, and in an embodiment, the deviation of the semiconductor process may be reduced by changing a phase of the first RF power and a phase of the second RF power. Therefore, to reduce the deviation of the semiconductor process, it is advantageous to first accurately detect the phase of the first RF power supplied to the lower electrode 202 and the phase of the second RF power supplied to the upper electrode 204.

In an embodiment, by installing the first VI sensor 225 for detecting the first RF power and the second VI sensor 235 for detecting the second RF power, respectively, in the chamber housing 201, the phase of the first RF power and the phase of the second RF power may be accurately determined. As illustrated in FIG. 2, the first VI sensor 225 may be installed between the lower electrode 202 and an inner wall of the chamber housing 201, and the second VI sensor 235 may be installed between the upper electrode 204 and the inner wall of the chamber housing 201.

In an embodiment illustrated in FIG. 2, the first VI sensor 225 may be coupled to the lower rod 203, and the second VI sensor 235 may be coupled to the upper rod 205. Therefore, the lower electrode 202 and the upper electrode 204 may be located between the first VI sensor 225 and the second VI sensor 235 in a first direction, perpendicular to an upper surface of the electrostatic chuck 210.

For example, in the chamber housing 201, the first VI sensor 225 may be installed as close to the lower electrode 202 as possible, and the second VI sensor 235 may be installed as close to the upper electrode 204 as possible. Therefore, the phase of the first RF power actually applied to the lower electrode 202 may be accurately determined from a sensing signal of the first VI sensor 225, and the phase of the second RF power actually applied to the upper electrode 204 may be accurately determined from a sensing signal of the second VI sensor 235.

Since each of the first VI sensor 225 and the second VI sensor 235 may be installed in the chamber housing 201, in an embodiment, a first gap between the first VI sensor 225 and the lower electrode 202 may be equal to or similar to a second gap between the second VI sensor 235 and the upper electrode 204. For example, a difference between the first gap and the second gap may be minimized, and by minimizing asymmetry of the first VI sensor 225 and the second VI sensor 235, an error occurring in a process of determining the phase of the first RF power and the phase of the second RF power may be reduced. In this manner, by accurately determining the phase of each of the first RF power and the second RF power and controlling the first power supply 220 and the second power supply 230 based thereon, progress deviation of the semiconductor process according to a position of the wafer W may be reduced, and uniformity of the semiconductor process may be improved.

When a sensor for detecting RF power is installed outside the chamber housing 201 as in the related art, a harmonic component may not be accurately measured due to impedance mismatch or the like. By contrast, in an embodiment, by installing the first VI sensor 225 and the second VI sensor 235 in the chamber housing 201, respectively, a harmonic component of the first RF power and a harmonic component of the second RF power may be precisely measured. A magnitude of the harmonic component of the first RF power and a magnitude of the harmonic component of the second RF power may be known as a factor affecting uniformity of the semiconductor process, and in an embodiment, uniformity of the semiconductor process may be improved by respectively controlling the first RF power and the second RF power such that the harmonic component of the first RF power and the harmonic component of the second RF power may be reduced.

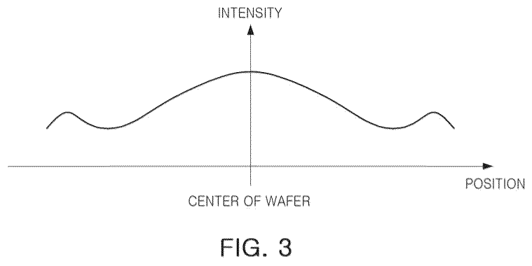

FIG. 3 is a view illustrating uniformity of a semiconductor process performed in semiconductor processing equipment according to an embodiment.

Referring to FIG. 3, progress of a semiconductor process performed on a wafer by semiconductor processing equipment according to an embodiment may be changed depending on a position of the wafer. For example, progress of a semiconductor process performed on a wafer may be relatively high at a center of the wafer, and may decrease toward an edge of the wafer. Depending on an embodiment, the progress of the semiconductor process may tend to increase in a region adjacent to the edge of the wafer.

A difference in progress of the semiconductor process may be caused by a standing wave effect, a skin effect, or the like. For example, due to the standing wave effect, an intensity of an electric field in a chamber housing may be high toward the center of the wafer, and as a result, the progress of the semiconductor process may be relatively high at the center of the wafer. The difference in the progress of the semiconductor process due to the standing wave effect, the surface effect, or the like may be prominent in semiconductor processing equipment in which RF power is applied only to a lower electrode.

A difference in progress of the semiconductor process according to a position of the wafer may be alleviated by applying RF power to an upper electrode as well as the lower electrode of the semiconductor processing equipment. In semiconductor processing equipment in which RF power is respectively applied to the lower electrode and the upper electrode, the difference in the progress of the semiconductor process according to the position of the wafer may be reduced by controlling a phase of first RF power applied to the lower electrode and a phase of second RF power applied to the upper electrode. Therefore, to efficiently reduce the difference in the progress of the semiconductor process according to the position of the wafer, it is advantageous to first accurately detect the phase of the first RF power and the phase of the second RF power.

In an embodiment, a first VI sensor for detecting the phase of the first RF power and a second VI sensor for detecting the phase of the second RF power may be installed in a space in the chamber housing together with the lower electrode and the upper electrode. For example, the first VI sensor may be coupled to a lower rod connected to the lower electrode, and the second VI sensor may be coupled to an upper rod connected to the upper electrode. Therefore, the first VI sensor may be located as close to the lower electrode as possible, and the second VI sensor may be located as close to the upper electrode as possible, such that the phase of the first RF power applied to the lower electrode and the phase of the second RF power applied to the upper electrode may be accurately determined.

In addition, by installing the first VI sensor and the second VI sensor in the space in the chamber housing, a harmonic component of the first RF power and a harmonic component of the second RF power may be accurately detected. The harmonic components of the RF power may be one of causes of lowering uniformity of a semiconductor process according to the position of the wafer, and magnitudes of the harmonic components may be reduced by controlling the phase of the first RF power and the phase of the second RF power. In an embodiment, the phase of the first RF power and the phase of the second RF power may be adjusted while monitoring the magnitudes of harmonic components respectively included in the first RF power and the second RF power. Therefore, by adjusting the phase of the first RF power and the phase of the second RF power such that the magnitudes of harmonic components respectively included in the first RF power and the second RF power may be minimized, uniformity of a semiconductor process may be improved.

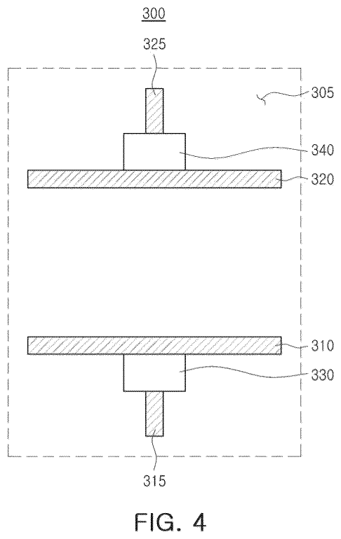

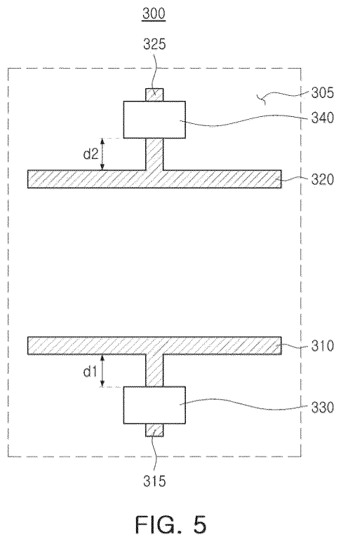

FIGS. 4 and 5 are views schematically illustrating semiconductor processing equipment according to an embodiment.

Referring to FIGS. 4 and 5, semiconductor processing equipment 300 according to an embodiment may include a lower electrode 310, a lower rod 315, an upper electrode 320, an upper rod 325, a first VI sensor 330, a second VI sensor 340, and the like, which may be disposed in an internal space 305 of a chamber housing. The first VI sensor 330 may be mounted on the lower rod 315, and the second VI sensor 340 may be mounted on the upper rod 325. The first VI sensor 330 may be installed between the lower electrode 310 and an inner wall of the chamber housing, and the second VI sensor 340 may be installed between the upper electrode 320 and the inner wall of the chamber housing. Referring to FIGS. 4 and 5, the lower electrode 310 and the upper electrode 320 may be located between the first VI sensor 330 and the second VI sensor 340 in a vertical direction.

In an embodiment illustrated in FIG. 4, the first VI sensor 330 may be installed in close contact with the lower electrode 310, and the second VI sensor 340 may be installed in close contact with the upper electrode 320. Therefore, the first VI sensor 330 may accurately detect first RF voltage and first RF current of the first RF power applied to the lower electrode 310 through the lower rod 315. In addition, the second VI sensor 340 may accurately detect second RF voltage and second RF current of the second RF power applied to the upper electrode 320 through the upper rod 325. In some embodiments, the first VI sensor 330 may be installed in direct contact with the lower electrode 310, and the second VI sensor 340 may be installed in direct contact with the upper electrode 320.

Depending on an embodiment, due to other devices installed around the lower electrode 310, the lower rod 315, the upper electrode 320, the upper rod 325, or the like, in some cases, it may be impossible to install the first VI sensor 330 in close contact with the lower electrode 310 and/or to install the second VI sensor 340 in close contact with the upper electrode 320. For example, in some cases, it may be possible to install the second VI sensor 340 in close contact with the upper electrode 320, whereas it may be impossible to install the first VI sensor 330 in close contact with the lower electrode 310.

In this case, when the second VI sensor 340 is installed in close contact with the upper electrode 320 separately from the first VI sensor 330, a gap between the first VI sensor 330 and the lower electrode 310 may be larger than a gap between the second VI sensor 340 and the upper electrode 320. Therefore, an error due to asymmetry of the first and second VI sensors 330 and 340 may be reflected in the first RF voltage and the first RF current detected by the first VI sensor 330 and the second RF voltage and the second RF current detected by the second VI sensor 340.

Referring to FIG. 5, in a case in which at least one of the first VI sensor 330 or the second VI sensor 340 cannot be installed in close contact with the electrodes 310 and 320, to resolve asymmetry of the VI sensors 330 and 340, the first VI sensor 330 may be installed to be separated from the lower electrode 310 by a first gap d1, and the second VI sensor 340 may be installed to be separated from the upper electrode 320 by a second gap d2. The first gap d1 and the second gap d2 may be substantially equal, and a ratio of the second gap d2 to the first gap d1 may have a value that does not greatly deviate from 1.0. In an embodiment, the ratio of the second gap d2 to the first gap d1 may be 0.8 to 1.2.

An installation location of the first VI sensor 330 and an installation location of the second VI sensor 340 may be determined according to the number and types of devices disposed in the internal space 305 of the chamber housing. In an embodiment, when it is difficult to install the sensors 330 and 340 in close contact with the electrodes 310 and 320, as illustrated in FIG. 5, the first VI sensor 330 may be installed to be separated from the lower electrode 310 by the first gap d1, and the second VI sensor 340 may be installed to be separated from the upper electrode 320 by the second gap d2, and the first gap d1 and the second gap d2 may be selected to be as equal as possible. Therefore, asymmetry between the first VI sensor 330 and the second VI sensor 340 may be minimized, and a phase of the first RF power and a phase of the second RF power may be accurately detected. In addition, by using the first VI sensor 330 and the second VI sensor 340 to adjust a phase of at least one of the first RF power or the second RF power with reference to the phase of the first RF power and the phase of the second RF power, uniformity of the semiconductor process may be improved.

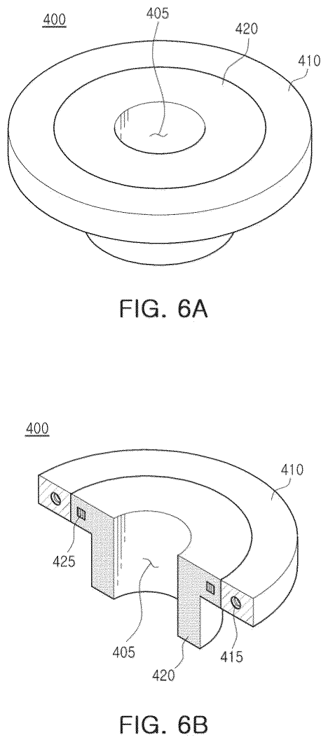

FIGS. 6A and 6B are views schematically illustrating a VI sensor included in semiconductor processing equipment according to an embodiment.

Referring to FIGS. 6A and 6B, a VI sensor 400 according to an embodiment may include a first insulating layer 410, a second insulating layer 420, a toroidal coil 415, a floating electrode 425, and the like. The first insulating layer 410 may have a shape surrounding an outer circumferential surface of the second insulating layer 420, and the second insulating layer 420 may include a through-region 405 that may be coupled to a rod connected to an electrode.

The VI sensor 400 may be coupled to the rod in a form in which the rod is inserted into the through-region 405 of the second insulating layer 420. A transmission path for supplying RF power output from a power supply to the electrode may be provided in the rod, and therefore, the toroidal coil 415 and the floating electrode 425 may be disposed in a form surrounding the transmission path for supplying RF power to the electrode. For example, the floating electrode 425 may have a cylindrical shape surrounding the rod.

The toroidal coil 415 may be connected to a current detection circuit of a controller controlling semiconductor processing equipment, and the floating electrode 425 may be connected to a voltage detection circuit of the controller. For example, when RF power is supplied to the electrode through the rod, an induced current may flow in the toroidal coil 415 due to the RF power. The current detection circuit may detect RF current corresponding to RF power supplied to the electrode through the rod by detecting the induced current flowing in the toroidal coil 415.

The first insulating layer 410 and the second insulating layer 420 may be formed of different materials having different permittivity. In some embodiments, the first insulating layer 410 disposed on the outside may be electrically connected to a chamber housing. When RF power is supplied to the electrode through the rod, a voltage of a voltage level may be applied to the floating electrode 425 by the first insulating layer 410 and the second insulating layer 420 and the chamber housing that may be electrically connected to and grounded by the second insulating layer 420. The voltage level may be predetermined. The voltage detection circuit may detect RF voltage corresponding to RF power supplied to the electrode through the rod by detecting the voltage applied to the floating electrode 425.

The controller may detect the RF power supplied to the electrode using the RF voltage and the RF current. For example, the controller may detect an amplitude, a phase, a frequency, or the like of the RF power. In an embodiment, the controller may determine a phase of first RF power supplied to a lower electrode and a phase of second RF power supplied to an upper electrode, respectively, and adjust the phase of at least one of the first RF power or the second RF power based thereon, thereby improving uniformity of a semiconductor process performed by the first RF power and the second RF power.

In some embodiments, the controller may detect a harmonic component included in the RF power using the VI sensor 400. The controller may include a frequency filter, a variable gain amplifier, a signal processing circuit, or the like, for extracting a harmonic component from a sensing signal of the VI sensor 400. The frequency filter may select and pass a frequency band corresponding to the harmonic component, for example, a frequency band corresponding to a multiple of a frequency of the RF power. The variable gain amplifier may reduce a magnitude of a signal passed through the frequency filter, and may output the same, and the signal processing circuit may detect a magnitude, a phase, or the like of the harmonic component.

As described above, the harmonic component included in the RF power may cause uniformity of a semiconductor process performed by the RF power to deteriorate. In an embodiment, a phase of the RF power as well as the harmonic component may be detected together using the VI sensor 400, and the phase of the RF power, or the like may be adjusted based on a detection result such that the harmonic components may be reduced. For example, the phase of the RF power may be adjusted such that an intensity of the harmonic component may be reduced to below a reference intensity. The reference intensity may be predetermined. By using the VI sensor 400 installed in the chamber housing, the harmonic component included in the RF power may be accurately detected regardless of a standing wave effect or the like, and deviation in progress of the semiconductor process according to a position of the wafer may be reduced with reference thereto.

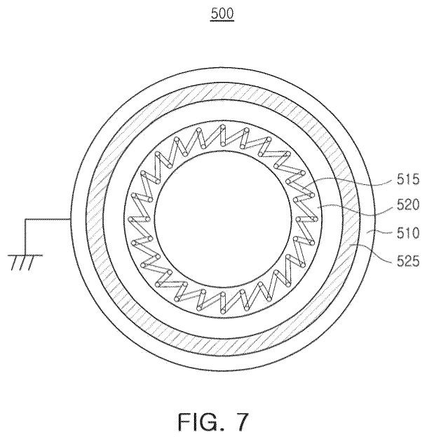

FIG. 7 is a view schematically illustrating a VI sensor included in semiconductor processing equipment according to an embodiment.

In an embodiment illustrated in FIG. 7, a VI sensor 500 may include a first insulating layer 510, a second insulating layer 520, a toroidal coil 515, a floating electrode 525, and the like. The first insulating layer 510 may be disposed on an outside of the second insulating layer 520, and the first insulating layer 510 and the second insulating layer 520 may be formed of materials having different permittivity.

Referring to FIG. 7, the toroidal coil 515 may be disposed in the second insulating layer 520, and the floating electrode 525 may be disposed in the first insulating layer 510. Unlike the embodiment described above with reference to FIGS. 6A and 6B, in the embodiment illustrated in FIG. 7, the toroidal electrode 515 may be disposed closer to a rod than the floating electrode 525.

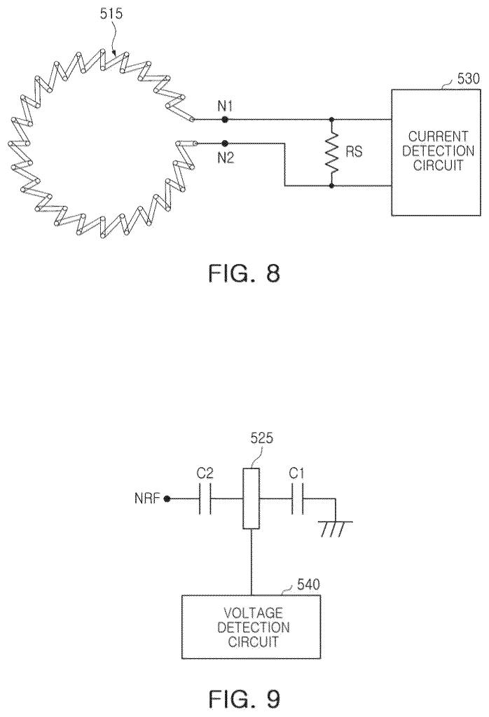

The VI sensor 500 may be disposed in an internal space of a chamber housing of semiconductor processing equipment, and the chamber housing may be formed of a conductive material such as aluminum or the like, and may be electrically grounded. The first insulating layer 510 may be electrically grounded through the chamber housing or another device. This configuration may be a configuration for detecting RF voltage corresponding to RF power through the floating electrode 525. Hereinafter, with reference to FIGS. 8 and 9, a method for detecting RF current and RF voltage, corresponding to RF power, using the VI sensor 500 will be described in more detail.

FIGS. 8 and 9 are views illustrating an operation of a VI sensor included in semiconductor processing equipment according to an embodiment.

First, FIG. 8 may be a view illustrating a method for detecting RF current corresponding to RF power using a toroidal coil 515. Referring to FIG. 8, both ends of the toroidal coil 515 may be connected to a first node N1 and a second node N2, and the first node N1 and the second node N2 may be connected to a current detection circuit 530. A shunt resistor RS may be connected between the first node N1 and the second node N2.

The toroidal coil 515 may be installed to surround an outside of a rod having a transmission path for supplying RF power to an electrode in a chamber. Therefore, when RF power is supplied to the electrode through an inside of the rod, an induced current may flow in the toroidal coil 515. The induced current flowing in the toroidal coil 515 may generate a voltage drop in the shunt resistor RS through the first node N1 and the second node N2, and the current detection circuit 530 may detect the voltage drop across the shunt resistor RS.

A voltage drop detected on both ends of the shunt resistor RS by the current detection circuit 530 may correspond to RF current. For example, a controller controlling semiconductor processing equipment may determine RF current by using the voltage drop on both ends of the shunt resistor RS detected by the current detection circuit 530.

Next, referring to FIG. 9, a floating electrode 525 may be connected to a voltage detection circuit 540. The floating electrode 525 may be embedded in a first insulating layer 510, as described above with reference to FIG. 7. Therefore, an equivalent circuit in which the floating electrode 525 is connected between a first capacitor C1 generated by the first insulating layer 510 and a second capacitor C2 generated by a second insulating layer 520 may be simulated as illustrated in FIG. 9.

The second capacitor C2 generated by the second insulating layer 520 may be defined as a capacitor between an RF node (NRF) corresponding to a transmission path through which RF power is supplied in a rod, and the floating electrode 525. Since the first insulating layer 510 may be electrically connected to a chamber housing or the like to be grounded, the first capacitor C1 may be defined as a capacitor between the ground node and the floating electrode 525.

The voltage detection circuit 540 may detect voltage of the floating electrode 525, and a controller of semiconductor processing equipment may determine RF voltage using the voltage of the floating electrode 525 and capacitance of the first capacitor C1 and capacitance of the second capacitor C2. According to an embodiment, the controller may filter the voltage of the floating electrode 525 measured by the voltage detection circuit 540 in a frequency band that may be a multiple of a frequency of the RF power, to determine a magnitude of a harmonic component included in the RF power.

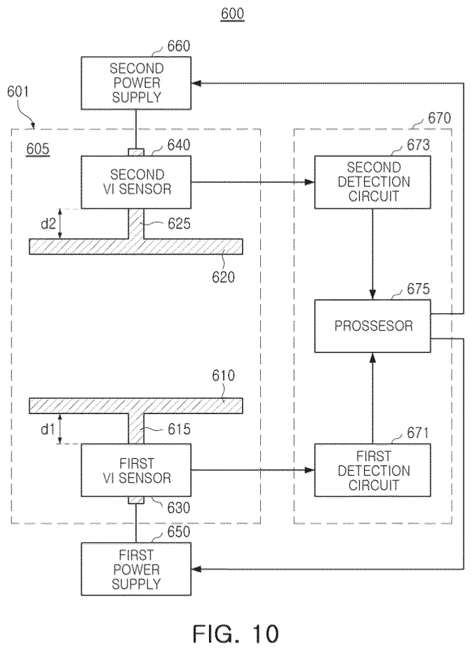

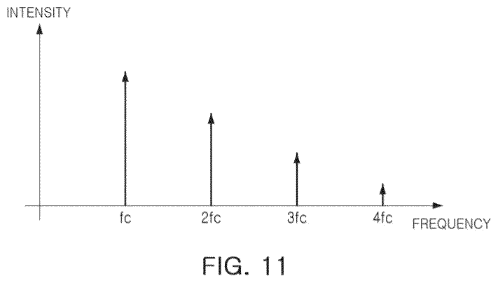

FIGS. 10 and 11 are views illustrating an operation of semiconductor processing equipment according to some embodiments.

First, referring to FIG. 10, semiconductor processing equipment 600 according to an embodiment may include a lower electrode 610, an upper electrode 620, a first VI sensor 630, a second VI sensor 640, and the like, which may be disposed in an internal space 605 of a chamber housing 601. In some embodiments, the semiconductor processing equipment 600 may further include a first power supply 650 supplying first RF power to the lower electrode 610 through a first rod 615, a second power supply 660 supplying second RF power to the upper electrode 620 through a second rod 625, a controller 670, and the like.

Configurations and operations of the lower electrode 610, the upper electrode 620, the first VI sensor 630, the second VI sensor 640, the first power supply 650, and the second power supply 660 can be understood with reference to the embodiments described above and thus a repeated description thereof is omitted for conciseness. For example, in an embodiment illustrated in FIG. 10, the first VI sensor 630 may be separated from the lower electrode 610 by a first gap d1, and the second VI sensor 640 may be separated from the upper electrode 620 by a second gap d2, but the first VI sensor 630 may be installed in close contact with the lower electrode 610, and the second VI sensor 640 may be installed in close contact with the upper electrode 620.

The controller 670 may include a first detection circuit 671, a second detection circuit 673, a processor 675, and the like. The first detection circuit 671 may be connected to the first VI sensor 630, and may detect first RF voltage and first RF current, corresponding to first RF power supplied by the first power supply 650 to the lower electrode 610. For example, the first detection circuit 671 may detect the first RF voltage and the first RF current in the same manner as described above with reference to FIGS. 8 and 9. Similarly, the second detection circuit 673 may be connected to the second VI sensor 640, and may detect second RF voltage and second RF current, corresponding to second RF power supplied by the second power supply 660 to the upper electrode 620.

The first detection circuit 671 may detect the first RF voltage and the first RF current multiple times, and may transmit a first sensing signal including detected first RF voltage and detected first RF current to the processor 675. The second detection circuit 673 may also detect the second RF voltage and the second RF current multiple times, and may transmit a second sensing signal including detected second RF voltage and detected second RF current to the processor 675. For example, each of the first detection circuit 671 and the second detection circuit 673 may detect the RF voltage and the RF current multiple times at different points in time.

The processor 675 may determine a phase of the first RF power using the first sensing signal, and may determine a phase of the second RF power using the second sensing signal. Since RF voltage and RF current for determining a phase of RF power may be detected from the VI sensors 630 and 640 installed in the internal space 605 of the chamber housing 601, the phase of the RF power may be accurately measured with a minimal error. In some embodiments, by installing the first VI sensor 630 and the second VI sensor 640 such that there may be no or very small error between the first gap d1 at which the first VI sensor 630 is separated from the upper electrode 610 and the second gap d2 at which the second VI sensor 640 is separated from the lower electrode 620, an error of a sensing signal due to asymmetry of positions at which the VI sensors 630 and 640 are installed, respectively, may be reduced. Therefore, a phase difference between the phase of the first RF power and the phase of the second RF power may be determined with a minimal error.

The processor 675 may adjust at least one of the phase of the first RF power or the phase of the second RF power. For example, due to the phase difference between the phase of the first RF power and the phase of the second RF power, an intensity of a first harmonic component included in the first RF power and/or an intensity of a second harmonic component included in the second RF power may increase, the increase may cause the uniformity of the semiconductor process performed in the semiconductor processing equipment 600 to deteriorate.

In an embodiment, by installing the VI sensors 630 and 640 in the internal space 605 of the chamber housing 601, the first harmonic component included in the first RF power and the second harmonic component included in the second RF power may also be accurately detected. The processor 675 may determine a magnitude of the first harmonic component and a magnitude of the second harmonic component while adjusting a phase of at least one of the first RF power or the second RF power. Therefore, the first RF power and the second RF power may be adjusted to have a phase in which the magnitude of the first harmonic component and the magnitude of the second harmonic component are minimized.

Referring to FIG. 11, a harmonic component included in RF power may appear in frequency bands 2fc, 3fc, and 4fc including a multiple of a center frequency fc of the RF power. To detect the harmonic component included in the RF power, a first detection circuit 671 and a second detection circuit 673 may include a frequency filter, a variable gain amplifier, or the like, respectively. The frequency filter may be a filter selectively passing a signal of each of the frequency bands 2fc, 3fc, and 4fc in which the harmonic component appears.

An intensity of each signal of the frequency bands 2fc, 3fc, and 4fc that have passed through the frequency filter may be adjusted by the variable gain amplifier, and the first detection circuit 671 and the second detection circuit 673 may detect an intensity of the harmonic component in each of the frequency bands 2fc, 3fc, and 4fc. A processor 675 may monitor whether the intensity of the harmonic component decreases while adjusting a phase of at least one of first RF power or second RF power, and determine a phase of the first RF power and a phase of the second RF power under conditions that the intensity of the harmonic component becomes minimal. In an embodiment, the processor 675 may determine the phase of the first RF power and the phase of the second RF power under the conditions that the intensity of the harmonic component becomes lower than a predetermined reference intensity.

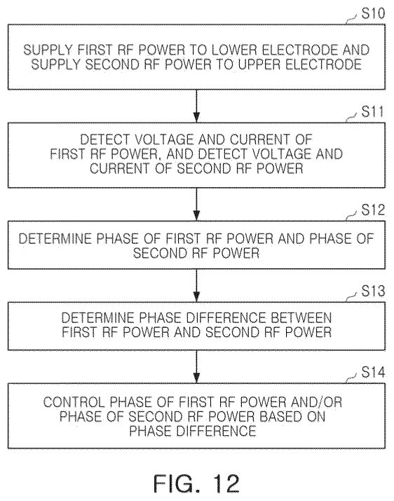

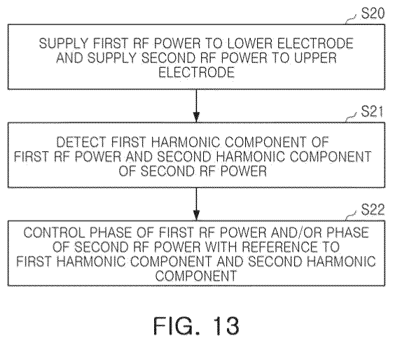

FIGS. 12 and 13 are flowcharts illustrating an operation of semiconductor processing equipment according to some embodiments.

First, referring to FIG. 12, an operation of semiconductor processing equipment according to an embodiment may start by supplying first RF power to a lower electrode and supplying second RF power to an upper electrode (S10). The semiconductor processing equipment may include a first power supply supplying the first RF power to the lower electrode and a second power supply supplying the second RF power to the upper electrode. Depending on an embodiment, a frequency of the first RF power and a frequency of the second RF power may be different from each other. In some embodiments, the frequency of the first RF power may not be greater than the frequency of the second RF power.

While the first RF power is supplied to the lower electrode and the second RF power is supplied to the upper electrode, a controller may detect voltage and current of the first RF power, and may detect voltage and current of the second RF power (S11). In an internal space of a chamber housing, a first VI sensor may be installed at a position close to the lower electrode, and a second VI sensor may be installed at a position close to the upper electrode. The controller may detect the voltage and current of the first RF power from the first VI sensor, and may detect the voltage and current of the second RF power from the second VI sensor. By installing the first VI sensor at a position close to the lower electrode, and installing the second VI sensor at a position close to the upper electrode, the voltage and current of the first RF power, and the voltage and current of the second RF power may be accurately detected.

The controller may determine a phase of the first RF power and a phase of the second RF power (S12), and may determine a phase difference between the first RF power and the second RF power (S13). A semiconductor process performed in the semiconductor processing equipment may have different progresses depending on a position in a direction, parallel to an upper surface of a wafer. The greater a difference in progress of the semiconductor process depending on a position on the wafer, the lower uniformity of the semiconductor process. For example, when the semiconductor process is an etching process, as uniformity of the semiconductor process deteriorates, even after a target layer of the etching process may be completely removed from a portion of semiconductor dies included in the wafer, the target layer of the etching process may remain in other semiconductor dies. Therefore, a yield of the semiconductor process may deteriorate.

The controller may control the phase of the first RF power and/or the phase of the second RF power based on the phase difference determined in S13. Uniformity of the semiconductor process may be improved by controlling the phase of the first RF power and the phase of the second RF power. For example, uniformity of the semiconductor process may be improved by reducing the phase difference between the first RF power and the second RF power. Therefore, to improve uniformity of the semiconductor process, it is advantageous to first accurately determine the phase of the first RF power and the phase of the second RF power.

In an embodiment, by installing both the first VI sensor and the second VI sensor in the internal space of the chamber housing, the controller may accurately determine the phase of the first RF power and the phase of the second RF power. In some embodiments, by installing the first VI sensor and the second VI sensor at appropriate positions, asymmetry between the first VI sensor and the second VI sensor may be reduced, such that the phase of the first RF power and the phase of the second RF power may be accurately determined. For example, a first gap between the lower electrode and the first VI sensor may be substantially the same as a second gap between the upper electrode and the second VI sensor. Considering other devices installed in the internal space of the chamber housing, the first VI sensor and the second VI sensor may be installed such that a difference between the first gap and the second gap may be minimized.

Next, referring to FIG. 13, an operation of semiconductor processing equipment according to an embodiment may start by supplying first RF power to a lower electrode and supplying second RF power to an upper electrode (S20). While the first RF power is supplied to the lower electrode and the second RF power is supplied to the upper electrode, a controller may detect a first harmonic component of the first RF power and a second harmonic component of the second RF power (S21). In S21, the controller may detect voltage and current of the first harmonic component and voltage and current of the second harmonic component. The controller may detect the voltage and current of the first harmonic component at different first detection points, and the voltage and current of the second harmonic component at different second detection points. The first detection points and the second detection points may be respectively matched with each other. For example, the controller may detect the voltage and current of the first harmonic component and the voltage and current of the second harmonic component at the same point.

The controller may control a phase of the first RF power and/or a phase of the second RF power with reference to the first harmonic component and the second harmonic component detected in S21 (S22). As described above, the first harmonic component of the first RF power supplied to the lower electrode and the second harmonic component of the second RF power supplied to the upper electrode may be a main cause of deteriorating uniformity of a semiconductor process performed in the semiconductor processing equipment.

In an embodiment, a first VI sensor and a second VI sensor may be installed close to the lower electrode and the upper electrode, respectively, in an internal space of a chamber housing. Therefore, the first harmonic component generated from the lower electrode and the second harmonic component generated from the upper electrode may be accurately detected without harmonic component attenuation due to impedance mismatch, or the like. The controller may adjust the phase of the first RF power and/or the phase of the second RF power while detecting the first harmonic component and the second harmonic component. By fixing the phase of the first RF power and/or the phase of the second RF power under conditions that the first harmonic component and the second harmonic component are minimized, uniformity of the semiconductor process may be improved.

According to an embodiment, a first sensor detecting RF power applied to a lower electrode and a second sensor detecting RF power applied to an upper electrode may be installed in a chamber housing. Therefore, the sensors may be disposed as close as possible to the lower electrode and the upper electrode, such that a phase and a harmonic component of the RF power may be accurately detected, and the RF power may be controlled based thereon, thereby improving uniformity of a semiconductor process performed on a substrate. In some embodiments, by disposing the sensors in the chamber housing, a gap between the lower electrode and the first sensor may not have a large difference from a gap between the upper electrode and the second sensor, and asymmetry of the first sensor and the second sensor may be reduced, such that the phase and the harmonic component of the RF power may be detected more accurately.

Various advantages and effects of the various embodiments are not limited to the above-described contents, and will be more easily understood in the process of explaining specific embodiments.

While various example embodiments have been illustrated and described above with respect to the drawings, it will be apparent to those skilled in the art that modifications and variations could be made without departing from the scope of the present disclosure as defined by the appended claims.

What is claimed is:

1. A semiconductor processing equipment comprising:
a chamber housing;
an electrostatic chuck in the chamber housing;
a lower electrode below the electrostatic chuck in the chamber housing;
an upper electrode above the electrostatic chuck in the chamber housing;
a first power supply configured to supply first radio frequency (RF) power to the lower electrode;
a second power supply configured to supply second RF power to the upper electrode;
a first voltage and current (VI) sensor between the lower electrode and an inner wall of the chamber housing;
a second VI sensor between the upper electrode and the inner wall of the chamber housing; and
a controller configured to determine a phase of the first RF power using a sensing signal of the first VI sensor, determine a phase of the second RF power using a sensing signal of the second VI sensor, and control the first power supply and the second power supply, based on the phase of the first RF power and the phase of the second RF power.

2. The semiconductor processing equipment of claim 1, further comprising:
a lower rod connected to the lower electrode and providing a first transmission path for the first RF power; and
an upper rod connected to the upper electrode and providing a second transmission path for the second RF power,
wherein the first VI sensor is coupled to the lower rod, and the second VI sensor is coupled to the upper rod.

3. The semiconductor processing equipment of claim 2, wherein the first VI sensor is in direct contact with the lower electrode, and the second VI sensor is in direct contact with the upper electrode.

4. The semiconductor processing equipment of claim 2, wherein the first VI sensor is separated from the lower electrode by a first gap, and the second VI sensor is separated from the upper electrode by a second gap.

5. The semiconductor processing equipment of claim 4, wherein the first gap is substantially equal to the second gap.

6. The semiconductor processing equipment of claim 2, wherein the first VI sensor includes:
a first insulating layer,
a first coil embedded in the first insulating layer of the first VI sensor and wound in a toroidal shape,
a second insulating layer disposed inside the first insulating layer of the first VI sensor and having a first through-hole region coupled to the lower rod, and
a first floating electrode embedded in the second insulating layer of the first VI sensor, and
wherein the second VI sensor includes:
a first insulating layer,
a second coil embedded in the first insulating layer of the second VI sensor and wound in a toroidal shape,
a second insulating layer disposed inside the first insulating layer of the second VI sensor and having a second through-hole region coupled to the upper rod, and
a second floating electrode embedded in the second insulating layer of the second VI sensor.

7. The semiconductor processing equipment of claim 6, wherein, when the first RF power is supplied to the lower electrode, the controller detects a current induced in the first coil of the first VI sensor to determine a first RF current corresponding to the first RF power, and detects a voltage of the first floating electrode of the first VI sensor to determine a first RF voltage corresponding to the first RF power.

8. The semiconductor processing equipment of claim 6, wherein, when the second RF power is supplied to the upper electrode, the controller detects a current induced in the second coil of the second VI sensor to determine a second RF current corresponding to the second RF power, and detects a voltage of the second floating electrode of the second VI sensor to determine a second RF voltage corresponding to the second RF power.

9. The semiconductor processing equipment of claim 1, wherein, while the first RF power is supplied to the lower electrode and the second RF power is supplied to the upper electrode, the controller detects a first harmonic component of the first RF power from the first VI sensor, and detects a second harmonic component of the second RF power from the second VI sensor.

10. The semiconductor processing equipment of claim 9, wherein the controller controls the phase of at least one of the first RF power or the second RF power with reference to an intensity of the first harmonic component and an intensity of the second harmonic component.

11. A semiconductor processing equipment comprising:
a chamber housing;
an electrostatic chuck in the chamber housing;
a lower electrode below the electrostatic chuck in a first direction that is perpendicular to an upper surface of the electrostatic chuck, and connected to a lower rod providing a first transmission path of the first RF power;
an upper electrode above the electrostatic chuck in the first direction and connected to an upper rod providing a second transmission path of the second RF power;
a first voltage and current (VI) sensor coupled to the lower rod in the chamber housing; and
a second VI sensor coupled to the upper rod in the chamber housing.

12. The semiconductor processing equipment of claim 11, wherein the first VI sensor is in direct contact with the lower electrode, and the second VI sensor is in direct contact with the upper electrode.

13. The semiconductor processing equipment of claim 11, wherein the first VI sensor is separated from the lower electrode by a first gap, and the second VI sensor is separated from the upper electrode by a second gap.

14. The semiconductor processing equipment of claim 11, wherein the first VI sensor includes a first coil having a toroidal shape and surrounding the lower rod, a first floating electrode having a cylindrical shape and surrounding the lower rod, and at least one first insulating layer in which the first coil and the first floating electrode are embedded, and
wherein the second VI sensor includes a second coil having a toroidal shape and surrounding the upper rod, a second floating electrode having a cylindrical shape and surrounding the upper rod, and at least one second insulating layer in which the second coil and the second floating electrode are embedded.

15. The semiconductor processing equipment of claim 14, wherein the at least one first insulating layer is electrically grounded through the chamber housing, and the at least one second insulating layer is electrically grounded through the chamber housing.

16. A semiconductor processing equipment comprising:
a chamber housing;
an electrostatic chuck in the chamber housing;
a lower electrode below the electrostatic chuck and receiving first RF power;
an upper electrode above the electrostatic chuck and receiving second RF power that is generated independently of the first RF power;
a first voltage and current (VI) sensor in the chamber housing closer to the lower electrode than to the upper electrode;
a second VI sensor in the chamber housing closer to the upper electrode than to the lower electrode; and
a controller configured to detect a first harmonic component included in the first RF power from the first VI sensor, detect a second harmonic component included in the second RF power from the second VI sensor, and control a phase of at least one of the first RF power or the second RF power with reference to the first harmonic component and the second harmonic component.

17. The semiconductor processing equipment of claim 16, wherein the controller detects a first voltage and a first current of the first harmonic component at a plurality of first sensing points, and detects a second voltage and a second current of the second harmonic component at a plurality of second sensing points.

18. The semiconductor processing equipment of claim 17, wherein the plurality of first sensing points are matched with the plurality of second sensing points, respectively.

19. The semiconductor processing equipment of claim 16, wherein the controller controls the phase of at least one of the first RF power or the second RF power such that an intensity of the first harmonic component and an intensity of the second harmonic component is reduced to be equal to or less than a reference intensity.

20. The semiconductor processing equipment of claim 16, wherein the lower electrode and the upper electrode are located between the first VI sensor and the second VI sensor in a first direction that is perpendicular to an upper surface of the electrostatic chuck.
